(19) United States
(12) Patent Application Publication
(10) Pub. No.: US 2012/0234229 A1
(43) Pub. Date: Sep. 20, 2012

(54) SUBSTRATE SUPPORT ASSEMBLY FOR THIN FILM DEPOSITION SYSTEMS

(75) Inventors: Tuan Anh NGUYEN, Santa Clara, CA (US); Donald J.K. Olgado, Palo Alto, CA (US); David H. Quach, San Jose, CA (US)

(73) Assignee: APPLIED MATERIALS, INC., Santa Clara, CA (US)

(21) Appl. No.: 13/419,247

(22) Filed: Mar. 13, 2012

Related U.S. Application Data
(60) Provisional application No. 61/453,392, filed on Mar. 16, 2011.

(51) Int. Cl. C30B 25/12; B23Q 3/00

(52) U.S. Cl. 117/88; 269/289 R; 118/59; 118/719

(57) ABSTRACT

Substrate support assemblies and deposition chambers employing such support assemblies to improve temperature uniformity during film depositions, such as epitaxial growths of group-V material stacks for LEDs. In one embodiment, the support assembly includes a first component having a first thermal resistance and a top surface upon which the substrate is to be disposed at a first location. The support assembly further includes a second component to be disposed over the first component and cover a second location of the susceptor while the substrate is disposed over the first location and having a second thermal resistance to insulate regions of the susceptor adjacent to the substrate by an amount approximating that of the substrate during a deposition process. In embodiments, the second component is removable from the first component and supports the substrate in absence of the first component during transfer of the substrate between multiple deposition systems.

### CROSS REFERENCE TO RELATED APPLICATIONS

This application claims the benefit of U.S. Provisional Application No. 61/453,392 (Attorney Docket No. 015724LAEPNEONESONG) filed on Mar. 16, 2011, entitled SUBSTRATE SUPPORT ASSEMBLY FOR THIN FILM DEPOSITION SYSTEMS, the entire contents of which are hereby incorporated by reference in its entirety for all purposes.

### TECHNICAL FIELD

Embodiments of the invention are in the field of thin film deposition and more particularly relate to a substrate support assembly for thin film deposition systems.

### BACKGROUND

Substrate heating during thin film deposition processes, particularly epitaxial growth processes which are performed at high temperatures ranging from 700° C. to 1300° C., can suffer temperature induced substrate deformation. Depending on mismatch of thermal expansion coefficients between a substrate and various materials disposed on the substrate, a substrate may bow in a convex manner (i.e., substrate center disposed a greater distance from an underlying flat support than substrate edges to have a positive radius of curvature) or concave manner (i.e., substrate edges disposed a greater distance from an underlying flat support than substrate center to have a negative radius of curvature) during film deposition. Such bowing can lead to uneven heating of the substrate as thermal coupling between the substrate backside and underlying support varies with substrate bow. Uneven heating may, in turn, induce nonuniformity in film material properties across the substrate. For certain applications (e.g., light-emitting diodes (LED), power transistors, etc.) in which a plurality of group III-V films are grown on a substrate to form a stack, substrate bow may vary by degree or even alternate between concave and convex as different films of the film stack are grown at different process temperatures.

Many deposition systems employed to perform epitaxial thin film growths utilize a carrier to support one or more substrates during transfer to a deposition chamber as well as during the film growth. It is therefore difficult to compensate for a substrate bow which varies in degree or varies in sign (concave vs. convex) during successive processing operations which are conducted at different process temperatures.

Additionally, as the carrier dimensions can be quite large (e.g., 300 mm or more), depending on the diameter of the substrate and number of substrates supported at any given time, a heated carrier may further radiate heat to other portions of a deposition chamber, for example a gas showerhead, which is often maintained at a temperature below that of the substrate and/or carrier. Such radiation can induce cool spots across the carrier and also cause the carrier to reach different average temperatures as different films of a stack are grown a particular substrate or set of substrates. Carrier cool spots and variation in the average carrier temperature also effect substrate temperature during film growth and are additional sources of variation in grown film properties.

As such, depending on the substrates and processes performed by a deposition chamber, a significant variation in properties of the films formed on each substrate, between multiple substrates, within a process run (i.e., single growth), and/or across multiple growths (i.e., run-to-run) may adversely affect device yield. A carrier assembly, as well as a deposition system and growth method employing such a carrier assembly, which can reduce these growth temperature non-uniformities is advantageous.

### BRIEF DESCRIPTION OF THE DRAWINGS

Embodiments of the present invention are illustrated by way of example, and not limitation, in the figures of the accompanying drawings in which:

FIG. 1A illustrates an isometric view of a substrate support assembly for supporting a substrate during a deposition process, in accordance with an embodiment;

FIG. 1B illustrates isometric views of a first and second component of the substrate assembly depicted in FIG. 1A;

FIGS. 2A, 2B, and 2C illustrate cross-sectional views of a first component of the substrate support assembly, the first component assembled with the second component, and a substrate disposed on the substrate support assembly, in accordance with embodiments;

FIG. 3A illustrates an expanded view of a carrier component of a substrate support assembly, in accordance with and embodiment;

FIG. 3B illustrates an expanded view of a carrier component depicted in FIG. 3A when supporting a substrate, in accordance with an embodiment;

FIG. 3C illustrates an isometric view of a robotic handler positioning the carrier component illustrated in FIG. 3B on a susceptor component, in accordance with an embodiment;

FIG. 3D illustrates a plan view of a substrate disposed on a pedestal surface with a carrier component surrounding the pedestal, in accordance with an embodiment;

FIG. 4 illustrates a multi-chambered deposition system, in accordance with an embodiment; and

FIG. 5 illustrates a method of epitaxially growing a stack of films, in accordance with an embodiment.

### DETAILED DESCRIPTION

In the following description, numerous details are set forth. It will be apparent, however, to one skilled in the art, that the present invention may be practiced without these specific details. In some instances, well-known methods and devices are shown in block diagram form, rather than in detail, to avoid obscuring the present invention. Reference throughout this specification to “an embodiment” means that a particular feature, structure, function, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the two embodiments are not mutually exclusive.

Substrate carriers made of silicon carbide (SiC) have high emissivity coefficient c and high thermal conductivity k (i.e., low thermal resistivity, Km/W). In comparison with SiC, a substrate, often sapphire, typically has low emissivity coefficient and low thermal conductivity. For such a carrier/substrate material combination, most of the heat and radiant energy from the carrier will transfer to nearby chamber components, such as a gas showerhead disposed above the carrier, via the regions of a carrier not covered by a substrate. While high carrier emissivity and thermal conductivity is beneficial in regions disposed below a substrate for heating of the substrate 103 by the carrier, in certain circumstances it is advantageous to reduce energy transferred from the carrier to the chamber. For example, where a gas showerhead is cooled to a temperature of about 30° C.-300° C., well below that of the substrate (heated to 700° C.-1300° C., or more, by the carrier which is heated, for example via lamps, resistive elements, or induction coils disposed below the carrier,), carrier temperature uniformity and showerhead performance may be improved by reducing heat loss from the carrier to the showerhead.

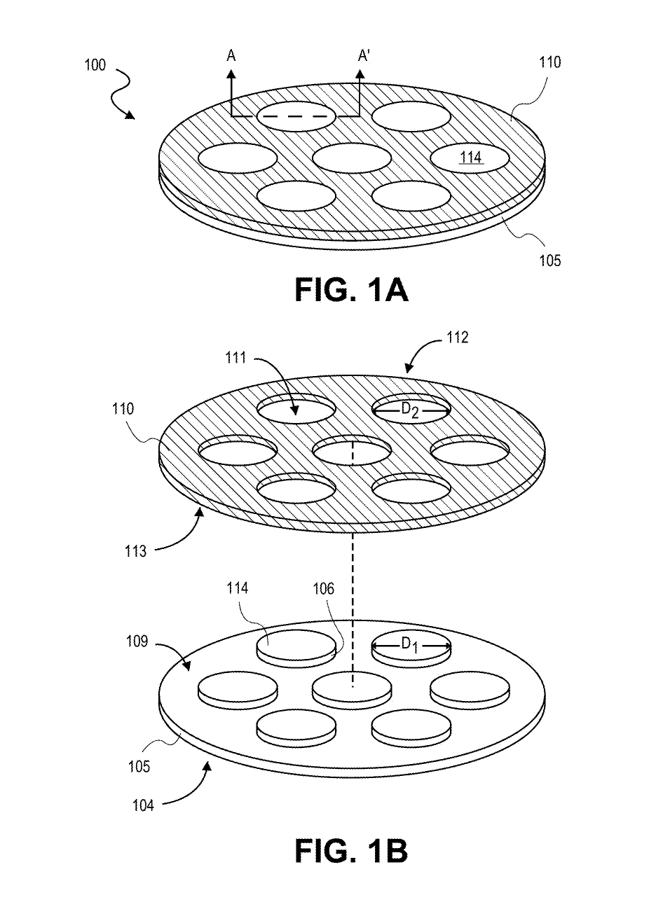

FIG. 1A illustrates an isometric view of a substrate support assembly 100 for supporting a substrate during a deposition process, in accordance with an embodiment. The support assembly 100 includes at least two components, 105 and 110. Component 105 has low thermal resistance and may further have a high emissivity to transfer heat to a substrate which is to be disposed on a support 114 of the component 105 during a deposition process. Second, component 110 having a higher thermal resistance is disposed over, and may further be disposed directly on, the component 105 to surround the support 114.

Generally, the thermal resistance provided by component 110 is to better approximate the thermal resistance of the substrate than does the component 105 to thermally insulate peripheral regions of the component 105 by an amount approximately equal to the amount by which a substrate disposed on the support 114 thermally insulates the component 105. In the exemplary embodiment, the thermal resistance of component 110 is approximately equal to the thermal resistance of the substrate. The thermal resistance may be matched to that of a particular substrate, be it sapphire, silicon or otherwise, by forming the component 110 of a material having a particular thermal conductivity and particular thickness. In further embodiments, component 110 has a lower emissivity than component 105. In certain such embodiments, component 110 has an emissivity approximately equal to that of the substrate to match the thermal transmission through the support 114 with that occurring through peripheral regions of the substrate support assembly 100. As such, material composition of the components 105 and 110 is a matter of design choice with only a few exemplary materials and thicknesses describe for the sake of illustration herein.

FIG. 1B illustrates exploded isometric views of the separate components 105 and 110 of the substrate assembly 100 depicted in FIG. 1A. As shown, the component 105 has a top side 109 and a bottom side 104. In an embodiment, the bottom side 104 is to be disposed over a heat source, such as one or more lamps. Depending on the size of the substrates, one or more of the supports 114 are present on the top side 109 (e.g., seven substrate locations are depicted in FIG. 1). In the exemplary embodiment, the first component 105 further comprises a pedestal 106 raised a distance above the surrounding surface of top side 109. The pedestal 106 has a diameter D₁ which is sized depending on the embodiment to be approximately equal to, slightly smaller than, or slightly larger than the substrate. In exemplary embodiments, component 105 is of silicon carbide or aluminum, with other embodiments employing materials known in art to be suitable for a susceptor in thin film deposition chambers.

The component 110 includes a top side 112 and a bottom side 113 with the component 110 configured to mate to the component 105 so that the bottom side 113 is facing the top side 109. The component 110 is generally a disk having one or more through openings 111 of a diameter D₂ sized to clear the support(s) 114 (i.e., D₂ is at least equal to D₁). The component 110 is to be disposed over the component 105, as shown in FIG. 1A, during a deposition process. The top side 112 is to remain uncovered by any substrate during processing. In exemplary embodiments, the component 110 is of quartz or sapphire, with other embodiments employing materials known in art to have similarly high temperature stability, high thermal resistance (e.g., low thermal conductivity) and low particulates.

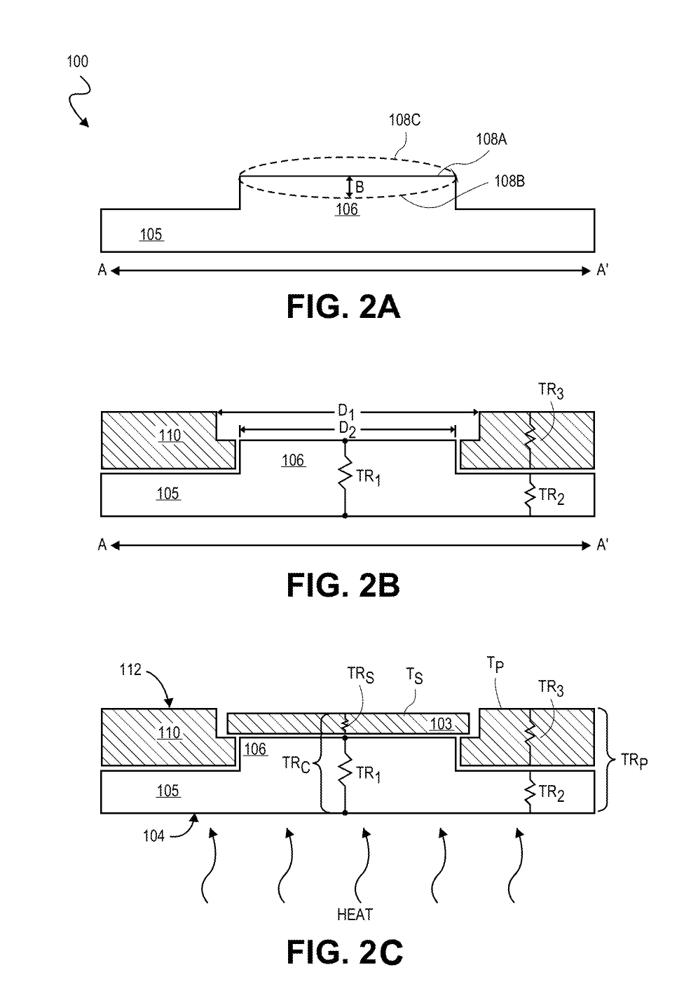

FIGS. 2A, 2B, and 2C illustrate cross-sectional views of the component 105, the component 105 assembled with the component 110, and a substrate 103 disposed on the substrate support assembly 100, in accordance with embodiments. As shown in FIG. 2A, in various embodiments, the pedestal 106 has a planar or flat top surface 108A, a concave top surface 108B, or convex top surface 108C to accommodate a predetermined bow that will occur in the substrate to be disposed on the pedestal 106 (e.g., at deposition process temperature). The vertical displacement, B, of a concave top surface may be 200 μm or more, depending on the deposition process performed, substrate properties, and various film stack stresses.

As shown in FIG. 2B, with the component 110 disposed over the component 105 the pedestal 106 has a thermal resistance, TR₁, while at an adjacent region the component 105 has a thermal resistance, TR₂ which is supplemented by the component 110 having a thermal resistance, TR₃. In an embodiment, the serial sum of TR₃ and TR₂ is greater than TR₁ by approximately the thermal resistance of the substrate. For example, as further shown in FIG. 2C, with a substrate 103 disposed on the pedestal the thermal resistance of the substrate, TR₂ adds to TR₁ for a total thermal resistance at a substrate center of TR_{C}. In the periphery, TR₁ adds to TR₃ (along with any interface and gap resistance components) for a resistance at the periphery of TR_{P}. In the exemplary embodiment TR_{P} is approximately equal to TR_{C} (i.e., within 10%) to reduce any center to edge thermal gradient. As such, when heat is applied to a subsurface (e.g., bottom side 104) during a bottom-up heating process, a substrate topside surface temperature T_{S} is approximately equal to a peripheral support assembly top surface temperature T_{P} (i.e., within 10%).

Heights of the pedestal 106, and thickness of the second component 110 may be predetermined based on the thermal conductivity of the component 110 to have the top side 112 disposed at predetermined height relative to the substrate, for example to contain/position the substrate 103 during process and/or to reduce particulates resulting from sidewall deposition mechanisms). In an embodiment, the component 110 has a thermal conductivity which is lower than the thermal conductivity of the component 105. The component 110 may be selected to have a thermal conductivity which is sufficiently low that TR_{P} is approximately equal to TR_{C} while the top side 112 is substantially flush, slightly below, or slightly above the top surface the substrate 103 when seated upon the pedestal 106 with the exemplary embodiments having the pedestal height at least equal to the thickness of the component 110.

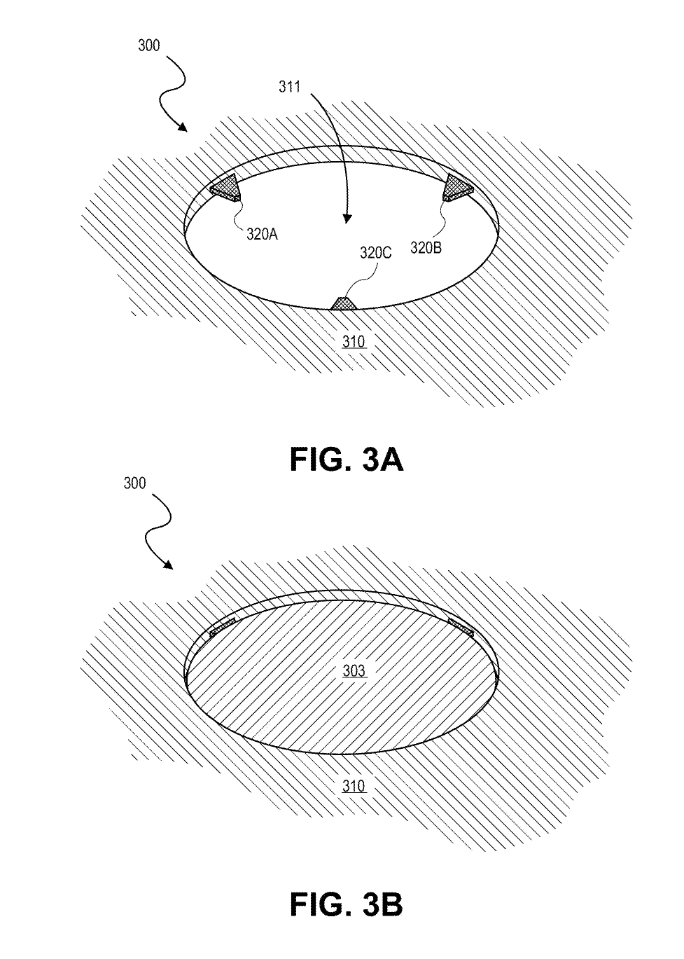

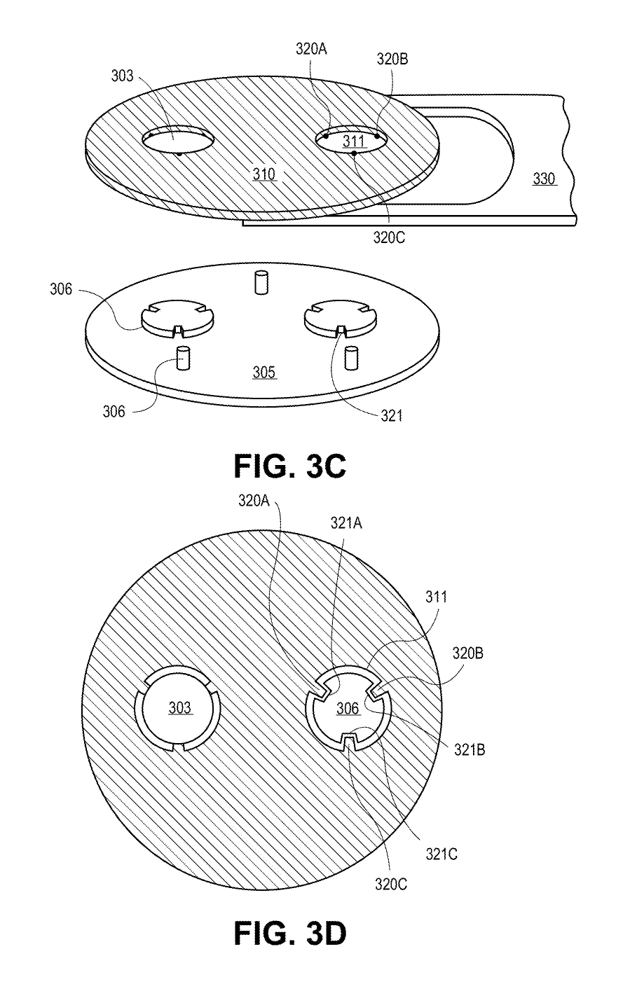

In an embodiment, the component 110 is removably disposable upon the component 105 and the component 110 is configured to support a substrate in absence of the first component. As such, the component 110 may serve as a substrate carrier 310 (illustrated in FIG. 3A) and the component 105 may serve as a susceptor 305 (illustrated in FIG. 3D) which interlocks with the carrier 310 while maintaining all the thermo-mechanical properties described elsewhere herein for benefit of thermal uniformity during film deposition. In one such embodiment, the susceptor 305 is to remain in a particular deposition chamber while the carrier 310 is to transfer to and from one or more deposition chambers along with substrates being processed. The susceptor 305 is to be rigidly affixed to the deposition chamber using any mechanical means while the carrier 310 is removably disposed on the susceptor 305 to remain in chamber during a deposition process. For such embodiments, in addition to the physical properties previously described for the component 110, the carrier 310 is to be of a material, and with sufficient thickness, to provide support and toughness suitable for substrate transfer. Exemplary carrier materials include any previously described for component 110, such as quartz or sapphire.

FIG. 3A illustrates an expanded view of a carrier 310 in a substrate support assembly 300, in accordance with and embodiment. As shown within the opening 311 are a plurality of tabs 320A, 320B, and 320C projecting radially toward the center of the opening 311. The plurality of tabs is to provide a means of interference to support a substrate within the opening 311. As illustrated in FIG. 3B, a substrate 303 is disposed on the plurality of tabs to span the opening 311.

FIG. 3C illustrates an isometric view of a robotic handler 330 positioning the carrier 310 on a susceptor 305, in accordance with an embodiment. As shown, the carrier 310 includes the substrate 303 in one opening 311 while a second opening 311 is vacant for illustrating the tabs 320A, 320B, and 320C. The handler 330 is to align the carrier 310 relative to the susceptor 305 with the openings 311 disposed over the pedestals 306. During a chamber load sequence, the carrier 310 is lowered onto pins 309 and the handler 330 removed from the chamber. Pins 309 then lower the carrier 310 onto the susceptor 305 to contact the substrate 103 with a top surface of the pedestal 306. Depending on the embodiment, the pedestal 306 has a diameter dimensioned to allow the carrier surfaces supporting the substrate 303 to be recessed below the top surface of the pedestal 306 such that support of the substrate 303 is alternated from the carrier 310 to the pedestal 306.

With the carrier 310 separable from the susceptor 305, the pedestal 306 to specific for a particular process and/or deposition chamber. For example, as described further elsewhere herein, a first deposition chamber may include a first susceptor 305 having a pedestal 306 with a concave top surface to accommodate a first substrate bow while a second deposition chamber may include a second susceptor 305 having a pedestal 306 with a flat or even convex top surface to accommodate a second degree, or direction, of substrate bow. Furthermore, because the susceptor 305 remains disposed in the chamber, the thermal mass of susceptor 305 is unconstrained and may be increased as there is no weight constraint imposed by the robotic handler 450. Greater thermal mass improves temperature uniformity and may also reduce warping of the support surface relative to a single-component carrier. These benefits are achieved while the opening 311 maintains a high heat transfer because, as shown in FIG. 2C, the thermal resistance between the substrate and a subsurface heat source is that of the susceptor only.

FIG. 3D illustrates a plan view of a substrate disposed on a pedestal surface with a carrier surrounding the pedestal, in accordance with an embodiment. In the exemplary embodiment illustrated in FIG. 3D, the pedestal 306 further comprises a plurality of pedestal slots 321A, 321B and 321C, each pedestal slot providing clearance to each tab 320A, 320B, and 320C, respectively. Following a deposition process, the load sequence described for the interlocking susceptor 305 and carrier 310 may be reversed to pick the substrate off the pedestal 306 with the carrier 310 and then remove the carrier 310 with the robotic handler 330.

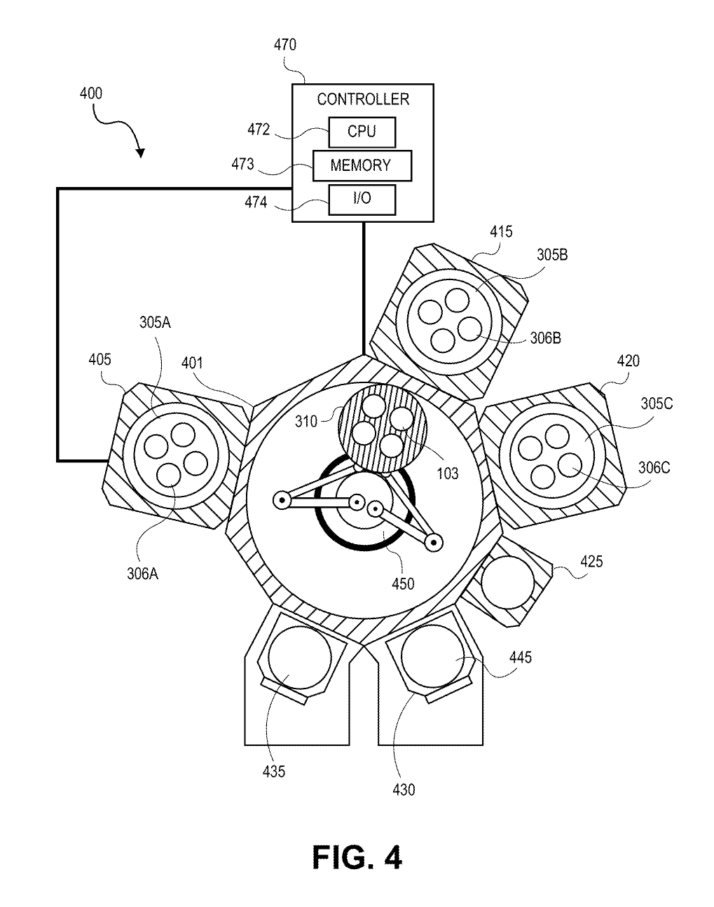

FIG. 4 illustrates a multi-chambered deposition system 400, in accordance with an embodiment. As shown in FIG. 4, two or more epitaxy chambers, such as two or more MOCVD chamber or HVPE chambers, or a combination of MOCVD and HVPE chambers, are coupled to a platform to form a multi-chambered deposition system 400. Embodiments described herein which utilize an intra-film stack transfer of the substrate between two deposition chambers may be performed using the multi-chambered deposition system 400. Referring to FIG. 4, the multi-chambered deposition system 400 may be any platform known in the art that is capable of adaptively controlling a plurality of process modules simultaneously. Exemplary embodiments include an Opus™ AdvantEdge™ system or a Centura™ system, both commercially available from Applied Materials, Inc. of Santa Clara, Calif.

The first, second, and third deposition chambers 405, 415, and 420 perform particular growth operations on a substrate 103. In the exemplary embodiment, the deposition chambers 405, 415, and 420 are separately dedicated to growth of p-doped layers (e.g., Mg-doped GaN layers) in the first deposition chamber 405, and growth of Mg-free films in the other chambers (e.g., MQW and undoped barrier layers in the second deposition chamber 415 and/or n-type doped GaN films in the third deposition chamber 420). Substrate 103 are transferred between the chambers 405, 415 and 420 as supported on the carrier 310 which is transferred by a robotic handler 450. As further depicted in FIG. 4, the multi-chambered deposition system 400 includes an optional substrate integrated metrology (IM) chamber 425, as well as load lock chambers 430 holding cassettes 435 and 445, coupled to the transfer chamber 401.

In an embodiment, each the deposition chambers 405, 415, and 420 includes a susceptor 305A, 305B, and 305C, respectively, with each susceptor having at least one pedestal, 306A, 306B, and 306C. In a further embodiment, a top surface of the pedestals 306A, 306B, 306C differ. For example, in a specific embodiment where the multi-chambered deposition system 400 is to grow a GaN-based LED stack and the first deposition chamber 405 is dedicated to growth of p-doped GaN layers, the pedestal 306A has a concave top surface to accommodate a concave substrate bow to improve temperature uniformity across the substrate during the p-doped GaN layer growth (a higher temperature operation often performed at 700° C. or more). In a further embodiment where the multi-chambered deposition system 400 is to grow a GaN-based LED stack and the second deposition chamber 415 is dedicated to growing a MQW (which is typically a lower temperature operation), the pedestal 306B has a flat or planar surface to accommodate a substrate with no significant bow. In a further embodiment, where the multi-chambered deposition system 400 is to grow a GaN-based LED stack and the third deposition chamber 420 is dedicated to growing an n-type doped GaN film, the pedestal 306C is has a concave top surface to accommodate a concave substrate bow to improve temperature uniformity across the substrate during the n-doped GaN layer growth (which is again typically a higher temperature operation). For these embodiments, with the carrier 310 serving as a transfer medium between chambers 405, 415 and 420 and the susceptors 305A, 305B, and 305C serving as the heat transfer medium in each chamber, different pedestals or “pocket” types are possible without changing carrier dimensions.

In one embodiment of the present invention, control of the multi-chambered deposition system 400, including the robotic handler 450, is provided by a controller 470. The controller 470 may be a system level controller, in which case it is in control of events in the transfer chamber 401 and may also be in communication with chamber-level controllers associated with each of the deposition chambers 405, 406 and 416. In other embodiments the controller 470 is a chamber level controller, in which case it is in control of events occurring only in a particular deposition chamber (e.g., the first deposition chamber 405). The controller 470 may be one of any form of general-purpose data processing system that can be used in an industrial setting for controlling the various subprocessors and subcontrollers. Generally, the system controller 470 or deposition chamber controller includes a central processing unit (CPU) 472 in communication with a memory 473 and an input/output (I/O) circuitry 474, among other common components. Software commands executed by the CPU 472, cause the multi-chambered deposition system 400 to, for example, load a substrate into the first deposition chamber 405, execute a first growth process, transfer the substrate to the second deposition chamber 415 and execute a second growth process.

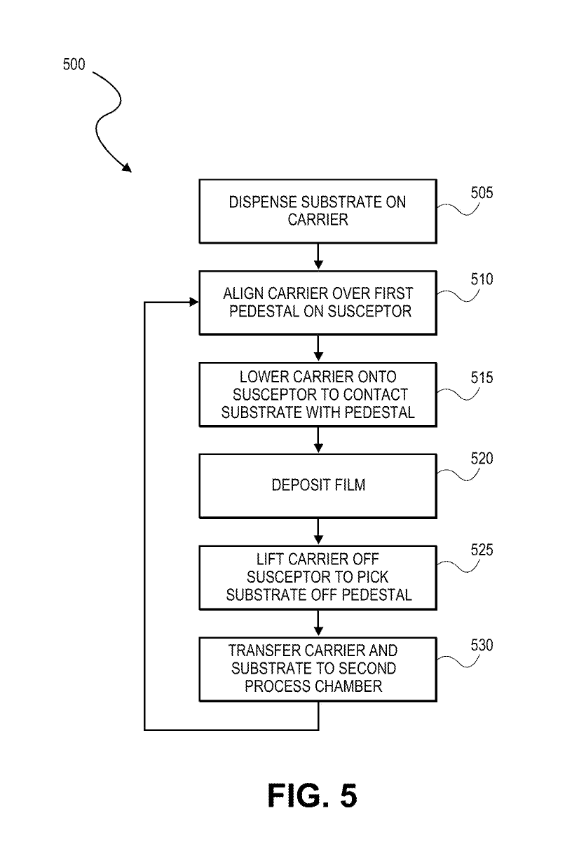

FIG. 5 illustrates a method 500 for epitaxially growing a stack of films, in accordance with an embodiment. At operation 505, the substrate 103 is dispensed on the carrier 310. In one implementation, the substrate 103 is single crystalline sapphire (e.g., (0001)) and may be patterned or unpatterned. Other embodiments contemplated include the use of substrates other than sapphire substrates, such as, Silicon (Si), germanium (Ge), silicon carbide (SiC), gallium arsenide (GaAs), zinc oxide (ZnO), lithium aluminum oxide (γ-LiAlO₂).

At operation 510, the carrier 310 is loaded in to a first process chamber, such as the deposition chamber 405, and aligned over a pedestal, such as the pedestal 306A. The carrier 310 is then lowered onto susceptor 305 to contact a backside of the substrate 103 to a top surface of the first pedestal. At operation 520, a film is then deposited on the substrate 103. In one exemplary LED embodiment, one or more bottom n-type epitaxial layers is formed over a buffer and/or undoped layer at operation 520 as part of an LED or power transistor film stack. In the exemplary group III-nitride material system, a bottom n-type epitaxial layer may be any n-type group III-nitride based material, such as, but not limited to, GaN, InGaN, AlGaN. For this exemplary embodiment, the top surface of the pedestal 306A is concave to accommodate high growth temperature substrate bow.

At operation 525, the carrier 310 is lifted off the susceptor 305A, for example with lift pins 309 (FIG. 3C) to pick the substrate off the pedestal 306A. A robotic handler, such as the handler 330 (FIG. 3C), then transfers the carrier 310 to a second process chamber, such as deposition chamber 415, at which point method 500 returns to operation 510 for a second iteration. For the exemplary LED film stack, the deposition chamber 415 forms a single quantum wells (SQW), a double hetereostructures, or a multiple quantum well (MQW) structure on the substrate 103. Such structures may be any known in the art to provide a particular emission wavelength. In a certain embodiments, an MQW structure may have a wide range of indium (In) content within GaN. For example, depending on the desired wavelength(s), the MQW structure may have between about a 10% to over 40% of mole fraction indium as a function of growth temperature, ratio of indium to gallium precursor, etc. For this exemplary embodiment, the top surface of the pedestal 306B is flat to accommodate low growth temperature substrate bow.

To complete an LED stack, a third iteration of the method 500 is performed, for example with the carrier 310 transferred with the substrate 103 into the deposition chamber 420 where one or more p-type epitaxial layers are disposed over the MQW structure on substrate 103. The p-type epitaxial layers may include one or more layers of differing material composition. For example, in one embodiment the p-type epitaxial layers include both p-type GaN and p-type AlGaN layers doped with Mg. In other embodiments only one of these, such as p-type GaN are utilized. For this exemplary embodiment, the top surface of the pedestal 306C is concave to accommodate high growth temperature substrate bow.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration. Accordingly, the specification and drawings are to be regarded in an illustrative sense rather than a restrictive sense.

What is claimed is:

1. A substrate support assembly for supporting a substrate during a deposition process, comprising:
a first component including a support upon which the substrate is to be disposed, wherein the first component has a first thermal resistance at a first location adjacent to the support;
a second component to be disposed over the first component and cover the first location without covering the support, wherein the second component comprises a material having a second thermal resistance, and wherein the sum of first and second thermal resistances is a better approximation of the sum of first thermal resistance and the thermal resistance of the substrate than is the first thermal resistance alone.

2. The substrate support assembly of claim 1, wherein the second thermal resistance is substantially equal to the thermal resistance of the substrate to thermally insulate the first component at the first location by an amount approximately equal to an amount the substrate thermally insulates the support.

3. The substrate support assembly of claim 1, wherein the second component has a thermal conductivity which is lower than the thermal conductivity of the first component.

4. The substrate support assembly of claim 1, wherein the first component comprises a material selected from the group consisting of: silicon carbide and aluminum.

5. The substrate support assembly of claim 4, wherein the second component comprises a material selected from the group consisting of: quartz and sapphire.

6. The substrate support assembly of claim 1, wherein the support comprises a pedestal, the pedestal having an area substantially equal to that of the substrate and of a height at least equal to the thickness of the second component, and wherein the second component comprises an opening of a diameter to clear the pedestal when aligned with the pedestal.

7. The substrate support assembly of claim 6, wherein the second component is removable from the first component, and wherein the second component includes a means to support the substrate in absence of the first component.

8. The substrate support assembly of claim 7, wherein the means to support the substrate in absence of the first component comprises a plurality of tabs projecting into the opening and wherein the pedestal further comprises a plurality of slots, each slot providing a clearance to each tab to support the substrate on a top surface of the pedestal when the second component is disposed over the first component.

9. The substrate support assembly of claim 7, wherein the first component comprises a plurality of pedestals and the second component comprises a plurality of openings disposed a same distance apart as the plurality of pedestals to alternately support a plurality of substrates with the first component and the second component as the second component is disposed on, and removed from, the first component, respectively.

10. The substrate support assembly of claim 7, wherein the pedestal further comprises a concave or convex top surface to accommodate a bow in the substrate.

11. A deposition chamber, comprising:
a susceptor, the susceptor having a top support surface upon which a substrate is to be disposed at a first location, wherein the susceptor is of a material having a first thermal resistance;
a carrier to support the substrate in absence of the susceptor and the carrier to be disposed over the susceptor to cover a second location of the susceptor while the substrate is in contact with the top support surface of the susceptor, wherein the carrier comprises a material having a second thermal resistance to reduce heat transfer through regions of the susceptor adjacent to the substrate.

12. The deposition system of claim 11, further comprising a heat source disposed below the top surface of the susceptor to heat the substrate.

13. The deposition system of claim 11, wherein the sum of first and second thermal resistances is a better approximation of the sum of first thermal resistance and a thermal resistance of the substrate than is the first thermal resistance alone.

14. The deposition system of claim 13, wherein the second thermal resistance is substantially equal to the thermal resistance of the substrate to thermally insulate the susceptor at the second location by an amount approximately equal to an amount the substrate insulates the susceptor at the first location.

15. The deposition system of claim 11, wherein the susceptor comprises a material selected from the group consisting of: silicon carbide and aluminum and wherein the carrier comprises a material selected from the group consisting of: quartz and sapphire.

16. The deposition system of claim 15, wherein the susceptor comprises a pedestal at the first location, the pedestal having an area substantially equal to that of the substrate and of a height at least equal to the thickness of the carrier to support the substrate while the carrier is disposed on the susceptor;
wherein the carrier comprises an opening aligned with the pedestal and of a diameter to clear the pedestal; and
wherein the carrier comprises a plurality of tabs projecting into the opening to support the substrate in absence of the susceptor.

17. A multi-chambered deposition system, comprising
a first and a second deposition chamber, each of the first and second deposition chambers as in claim 11, wherein the susceptor top surface upon which the substrate is to be disposed in the first deposition chamber is a first of concave, flat, or convex, and wherein the susceptor top surface upon which the substrate is to be disposed in the second deposition chamber is a second of concave, flat, or convex, different than the first.

18. The multi-chambered deposition system of claim 17, wherein the first deposition chamber is configured to grow a first portion of an LED stack and the susceptor top surface in the first deposition chamber is concave, and wherein the second deposition chamber is configured to grow a second portion of the LED stack and the susceptor top surface in the second deposition chamber is flat.

19. A method of depositing a film on a substrate, the method comprising:
disposing a substrate on a carrier, the carrier comprising an opening spanned by the substrate;
disposing the carrier on a first susceptor located within a first deposition chamber, wherein disposing the carrier on the first susceptor further comprises:
aligning the carrier opening with a first pedestal on the first susceptor; and
lowering the carrier to surround the first pedestal with a top surface of the pedestal disposed in the carrier opening and contacting the substrate; and
epitaxial growing a first film on the substrate.

20. The method of claim 19, further comprising:
lifting the carrier off the first susceptor to lift the substrate from the first pedestal;
transferring the carrier with the substrate to a second deposition chamber, and
disposing the carrier on a second susceptor located within a second deposition chamber to dispose the substrate on a second pedestal, wherein the first pedestal has a concave, flat, or convex top surface and the second pedestal has a concave, flat, or convex top surface, different than the first pedestal.
